(19) United States
(12) Patent Application Publication
(10) Pub. No.: US 2014/0071645 A1
(43) Pub. Date: Mar. 13, 2014

(54) Electronic Component comprising a Ceramic Carrier and use of a Ceramic Carrier

(71) Applicant: Robert Bosch GmbH, Stuttgart (DE)

(72) Inventors: Uwe Glanz, Asperg (DE); Stefan Henneck, Leonberg (DE); Alexander Martin, Regensburg (DE)

(73) Assignee: Robert Bosch GmbH, Stuttgart (DE)

(21) Appl. No.: 13/981,816

(22) PCT Filed: Jan. 31, 2012
(86) PCT No.: PCT/EP2012/051493

§ 371 Date: Nov. 12, 2013

(30) Foreign Application Priority Data
Feb. 2, 2011 (DE) 10 2011 003 481.1

(51) Int. Cl. H05K 1/11; H05K 3/10

(52) U.S. Cl. CPC H05K 1/111; H05K 3/10
USPC 361/771; 427/58; 427/123

(57) ABSTRACT

An electronic component for high-temperature applications includes a ceramic carrier and a semiconductor element. The ceramic carrier comprises a ceramic substrate having a content of alkali metal compounds of ≦0.5%, more particularly ≦0.05%, and the ceramic substrate is selected from the group consisting of: a ceramic substrate comprising aluminium oxide, anorthite, a filler having a coefficient of thermal expansion of ≦4.0*10⁻⁶K⁻¹ and glass; a ceramic substrate comprising aluminium oxide, celsian, a filler having a coefficient of thermal expansion of ≦4.0*10⁻⁶K⁻¹ and glass; and a ceramic substrate comprising an alkaline earth metal silicate glass having a silicon dioxide content of >50 mol %, boron oxide, and a filler having a coefficient of thermal expansion of <4.0*10⁻⁶K⁻¹. The component prevents temperature damage at high temperatures and has constant properties, such as electrical insulation properties, up to 500° C.

The present invention relates to an electronic component comprising a ceramic carrier and to a use of a ceramic carrier.

### PRIOR ART

The fixing of semiconductor elements, in particular based on silicon or silicon carbide, on a ceramic carrier is usually carried out using a corresponding fixing agent. In particular for semiconductor applications with high operating temperatures, this can be problematic since the thermal expansion coefficients of the semiconductor material and of the ceramic carrier are often very different from one another, so that there is a risk of damage to the electronic component, for example by stress cracks.

From DE 10 2008 008 535 A1, it is therefore known to fasten a field-effect transistor based on silicon carbide or sapphire, for example, on a ceramic carrier consisting of zirconium dioxide (ZrO₂) ceramic or aluminum oxide (Al₂O₃) ceramic by means of a fixing agent which is based on a metal, for instance silver. The fixing agent is in this case configured in such a way that it retains its fixing properties at operating temperatures of up to at least 500° C.

From DE 103 51 196 A1, it is furthermore known to use an LTCC material, the thermal expansion coefficient of which is as far as possible adapted to that of silicon, as the carrier material. To this end, a base material consisting of sodium-containing borosilicate glass plus aluminum oxide (Al₂O₃) is used, which is suitable for anodic bonding with silicon chips. In order to adapt the thermal expansion coefficient of the material to that of silicon, defined partial substitution of the aluminum oxide by cordierite and/or silica glass is carried out.

### DISCLOSURE OF THE INVENTION

The present invention relates to an electronic component for high temperature applications in a temperature range of 250° C., in particular 400° C., comprising a ceramic carrier and a semiconductor element, wherein the ceramic carrier comprises a ceramic substrate that has an alkali metal compound content of 0.5%, in particular 0.05%, and wherein the ceramic substrate is selected from the group consisting of a ceramic substrate comprising aluminum oxide, anorthite, a filler having a thermal expansion coefficient of 4.0*10⁻⁶K⁻¹ and glass, a ceramic substrate comprising aluminum oxide, celsian, a filler having a thermal expansion coefficient of 4.0*10⁻⁶K⁻¹ and glass, and a ceramic substrate comprising an alkaline-earth metal silicate glass having a silicon dioxide content in a range of >50 mol %, boron oxide, and a filler having a thermal expansion coefficient of 4.0*10⁻⁶K⁻¹.

According to the invention, an electronic component is provided which has a semiconductor element on a ceramic carrier. The ceramic carrier is in this case made of a particular LTCC material. LTCC (Low Temperature Cofired Ceramics) materials are in this context, according to the invention, in particular materials which are used in order to produce a sintered ceramic carrier on the basis of a multilayer structure. Conductor tracks, capacitors, resistors, inductors and other functional elements may be provided between the individual ceramic layers. LTCC materials are based in particular on mixtures of glass and aluminum oxide, which in most cases are converted into a composite material by a reactive sintering process. Besides parts of the original aluminum oxide particles and a glass phase, the composite material also contains a newly formed crystalline third phase. Owing to the newly formed crystalline phase, the thermal expansion coefficient of LTCC materials is lower than that of pure aluminum oxide, which is 7.9*10⁻⁶K⁻¹ (20-500° C.)

Owing to the composition, according to the invention, of the ceramic substrate, the crystalline phase comprises for example anorthite or celsian. Because of this, the thermal expansion coefficient of the ceramic substrate is ideally reduced considerably. Furthermore, such a ceramic material is heat-resistant up to much more than 500° C. and retains its properties into this temperature range.

According to the invention, the thermal expansion coefficient of the ceramic substrate is adaptable in the desired way to the desired application, i.e. in particular to the thermal expansion coefficient of the semiconductor material, for instance silicon or silicon carbide. To this end, the ceramic substrate comprises a filler having a thermal expansion coefficient of 4.0*10⁻⁶K⁻¹. In the ceramic substrate, this filler at least partially replaces the aluminum oxide so that a material having a lower thermal expansion coefficient is obtained, compared with a variant in which only aluminum oxide is used as the filler.

Particularly by such adaptation of the thermal expansion coefficient of the ceramic carrier to that of the semiconductor material, i.e. in particular silicon (Si) or silicon carbide (SiC), the ceramic carrier allows high temperature-resistant and temperature cycle-resistant fixing of for example semiconductor elements, for example semiconductor chips, based on silicon or silicon carbide, in a range of up to at least 500° C., as well as electrical connection thereof with an increased mechanical robustness of the joining connection.

According to the invention, it is furthermore provided that the ceramic carrier comprises a ceramic substrate that has an alkali metal compound content of 0.5%, in particular 0.05%. According to the invention, this describes in particular the alkali metal oxide content in the glass phase of the LTCC material. Consequently, essentially no alkali metal compounds are present in the ceramic carrier, but rather only a low proportion dependent on the technical purity of the raw materials used. There is therefore a high electrical insulation quality of the ceramic carrier, which makes the component according to the invention advantageous for a range of possible applications. These insulation properties are also manifested essentially unchanged even at the high working temperatures according to the invention, and are not substantially reduced in this case, so that the component according to the invention is particularly suitable in particular for high temperature applications. In this case, good undistorted signal transmission can be achieved, for example via conductor tracks arranged in the component.

Conductor tracks of the component according to the invention are in this case applied particularly by means of metal pastes based on silver and/or silver/palladium alloys onto the ceramic green films consisting of the described glass-ceramic composites by printing methods, for example by screen printing, and are processed further as is conventional for the production of LTCC multilayer systems (lamination, debinding, sintering). The outward feed-throughs of the contacts are likewise produced in a similar way to LTCC technology by filling stamped or bored through-holes in the films, a paste based on gold or a gold alloy, which is specially adapted to the sintering behavior of the ceramic, being used for this. The use of gold for the outwardly fed contacts is preferred in order to prevent electromigration processes of silver in a water- or pollutant gas-containing atmosphere. The internally lying conductor tracks are protected against chemical influences by the tightly sintered ceramic material, for which reason pastes made of economical silver alloys or pure silver can be used in this case. Likewise, however, these conductor tracks could also comprise gold or gold alloys in order to exclude silver migration absolutely, or nickel and copper, as well as alloys thereof with other metals, so long as the process of sintering the ceramic is carried out with exclusion of air.

The ceramic substrate of the component according to the invention can be produced straightforwardly, for instance by a reactive sintering process. As the starting substance, it is possible to use in this case an LTCC material which is based on a mixture of aluminum and glass. Depending on the composition of the glass, which may for example comprise calcium oxide (CaO), barium oxide (BaO), strontium oxide (SrO), boron oxide (B₂O₃), silicon oxide (SiO₂) and aluminum oxide (Al₂O₃), the corresponding ceramic substrate is formed in a reactive sintering process. By using a glass which essentially contains calcium oxide, boron oxide, silicon oxide and aluminum oxide, a ceramic substrate is formed which essentially comprises aluminum oxide, residual glass phase and anorthite (CaAl₂Si₂O₈). By using a glass which essentially contains barium oxide and/or strontium oxide, boron oxide, silicon oxide and aluminum oxide, a ceramic substrate is formed which essentially comprises aluminum oxide, residual glass phase and celsian (BaAl₂Si₂O₈ and/or SrAl₂Si₂O₈). The aluminum oxide, which has a high thermal expansion coefficient, is at least partially consumed during the formation of the anorthite and/or celsian. Anorthite and/or celsian are in this case precipitated as crystalline phases, so that the proportion of glass phase is reduced and particularly good thermal stability is therefore achieved, and at the same time the thermal expansion coefficient is reduced. According to the invention, a thermally stable filler having a low thermal expansion coefficient, for example cordierite, is furthermore added to the mixture, which filler then at least partially replaces the aluminum oxide, which has a very high thermal expansion coefficient. In this way, the thermal expansion coefficient can be adapted in the desired way to that of the semiconductor substrate. Mechanical stresses in relation to the applied semiconductor element are thereby kept low or avoided during temperature cycles.

Owing to the selection, according to the invention, of the ceramic substrate, sintering temperatures which lie in a low range are furthermore possible during the production of the ceramic carrier. For example, sintering temperatures of the ceramic in particular lower than 1200° C., particularly preferably in a range of from 800° C. to 1000° C., are possible. Because of the comparatively low temperatures which are required during the process of producing the ceramic carrier, it is possible to use economical noble metals or alloys such as silver (Ag) or silver/palladium (Aged) alloys for conductor tracks, or for instance a heating resistor. For example, owing to its low sintering temperature, the ceramic material may in this case be sintered together with economical conductor tracks embedded therein. The use of even more favorable and less noble metals, such as copper or nickel, for the internally lying conductor tracks or resistors may be envisioned with processing under a protective gas, although the increased process costs may then at least partially negate this price advantage.

The ceramic substrate comprising an alkaline-earth metal silicate glass having a silicon dioxide content in a range of >50 mol %, boron oxide, and a filler having a thermal expansion coefficient of 4.0*10⁻⁶K⁻¹, may in this case be made entirely without aluminum oxide. It is essentially amorphous and preferably has a very high glass transition temperature (TO, particularly in a range of from 700° C. to <850° C. Furthermore, the ceramic substrate preferably has a low thermal expansion coefficient, for example in a range of from 3.0*10⁻⁶K⁻¹ to 4.5*10⁻⁶K⁻¹, particularly preferably from 4.0*10⁻⁶K⁻¹ to <4.2*10⁻⁶K⁻¹. This, in particular, means a thermal expansion coefficient in a temperature range of 20-500° C. The thermal stability is provided by the high glass transition temperature of the glass and the low alkali metal compound content, likewise the good electrical insulation capability.

According to the invention, an electronic component is thus provided which can operate without problems at high temperatures, the thermal expansion coefficient of the ceramic substrate being, in particular, adapted to that of the semiconductor material. The ceramic substrate in this case maintains its strength and electrical insulation properties, which are necessary for a carrier substrate for a semiconductor element.

Direct connection of the chip, or semiconductor element, to the substrate is possible in this case. For example, a glass or a glass solder, a conventional ceramic adhesive, or ceramic plug packing, particularly with a similar thermal expansion coefficient, may be used. Furthermore, a configuration which is stable at high temperatures and/or sealed in a gastight fashion in relation to the medium to be measured can be achieved. This is because it is possible to save on complicated graded constructs with stepped thermal expansion coefficients and expensive ductile materials, for instance metals. In principle, economical contact and joining connections are therefore possible.

In the scope of an advantageous configuration of the electronic component according to the invention, the ceramic substrate has a thermal expansion coefficient which lies in a range of from 3.0*10⁻⁶K⁻¹ to 4.5*10⁻⁶K⁻¹, particularly preferably from 4.0*10⁻⁶K⁻¹ to 4.2*10⁻⁶K⁻¹. This, in particular, means a thermal expansion coefficient in a temperature range of 20-500° C. The ceramic substrate is therefore adapted particularly well to the thermal expansion coefficient of a semiconductor material. For example, the thermal expansion coefficient of silicon carbide is about 4.2*10⁻⁶K⁻¹ (20-500° C.) and that of silicon is 3.5*10⁻⁶K⁻¹ (20-500° C.) The electronic component is thus particularly highly suitable for high temperature applications, since risk of damage by temperature cycling, for instance due to stress cracks, can be almost entirely excluded.

In the scope of another advantageous configuration of the electronic component according to the invention, the filler contained in the ceramic substrate is selected from the group consisting of cordierite (Mg₄Al₄Si₅O₂₀), mullite (3Al₂O₃*2SiO₂ to 2Al₂O₂*1SiO₂), silicon nitride (Si₃N₄), silicon carbide (SiC), glass having a silicon dioxide content in a range of >50 mol %, or quartz glass (SiO₂ glass). These are inexpensive materials, which makes the production of the component according to the invention economical.

Furthermore, such fillers have a thermal expansion coefficient which is considerably lower than, for example, that of aluminum oxide, which is replaced by these fillers in the finished ceramic substrate. Typically, the thermal expansion coefficients of synthetic cordierite materials are, for example, 1.5-2.5*10⁻⁶K⁻¹ (20-500° C.). The aforementioned fillers furthermore have the advantage that they do not, or do not substantially, detrimentally affect the properties of the ceramic substrate, in particular the thermal stability, the sinterability or the insulation capability.

In the scope of another preferred configuration of the electronic component according to the invention, the ceramic substrate furthermore comprises sintering aids, for instance titanium dioxide or zirconium dioxide. These substances are used to control the sintering process and the crystallizations, and to permit sintering at low temperatures.

In the scope of another preferred configuration of the electronic component according to the invention, an electrically heatable heating element is arranged inside the ceramic carrier. The heating element is, in particular, arranged on a different layer plane of the multilayer structure of the LTCC material than the one carrying the conductor tracks, which provide the electrical contacting of the semiconductor element. The heating element may, for example, be formed as a resistor meander or as a flat resistor, for instance between two conductor tracks. By the heating element, independently of the ambient temperature of the electronic component, an adjustable temperature field can be generated and kept constant in the region of the semiconductor element, for instance the semiconductor sensor, by electrical heating. This configuration is advantageous particularly in the case of sensors, since these usually require an elevated temperature in order to generate a good and stable sensor signal.

In this case, it is particularly preferred for the heating element to comprise a metallic material, which comprises a noble metal or a noble metal alloy and at least one resistance-increasing material. In particular, the resistance-increasing material may comprise electrically insulating ceramic and/or vitreous particles, which are distributed in the metallic material, or with which the metallic material is permeated. In this way, the electrical resistance of the metallic material can be increased deliberately and in an accurately defined way, which, with a predetermined electrical voltage, achieves an accurately defined flow of current, or an accurately defined heating power. Particularly advantageously, the resistance-increasing particles consist of the same LTCC material as the ceramic substrate. Suitable as alternative resistance-increasing materials are conductive metal oxides, which have a higher resistivity compared with the metal with which they are mixed, for example ruthenium oxide or ruthenium oxide compounds. Other conductive mixed oxides, such as lanthanum chromites, manganites, cobaltites, ferrites and nickelites are also suitable for this, these otherwise being used primarily in the production of high temperature fuel cells. Suitable as metallic material are silver, palladium, gold or alloys of these noble metals, for example in the form of platelet-shaped and/or nanocrystalline particles. For the case of sintering the LTCC under a protective gas, for example forming gas, the metals copper and nickel are advantageous as constituents for the conductor tracks and the heating resistor, and can also be used with a proportion of said noble metals, above all gold and silver, in order to improve the sintering properties in the low temperature range. Since the heating resistor is enclosed in a gastight fashion in the LTCC after the sintering, the non-noble metals can also be stable since no oxygen access is possible. Optimal adaptation of the sintering shrinkage and the thermal expansion behavior is thereby achieved in the region of the heater, in order to make this thermally highly stressed region as robust as possible. In particular, an optimal sintered bond and a similar or identical expansion behavior can be achieved. In this way, the conductive metal particle content is reduced and the overall resistance in the conduction cross section of the printed conductor track is increased.

In the scope of a particularly advantageous configuration of the component according to the invention, the heating element comprises a composite of glass and an electrically conductive metal oxide, in particular ruthenium dioxide (RuO₂) or other electrically conductive ruthenium oxide compounds. The electrically conductive substance may in this case be formed as a filler in a glass matrix. The heating element may, in particular, be configured in a flat form in this configuration owing to its high resistivity. Besides ruthenium dioxide, other conductive ceramics may also be used, for example lanthanum manganite, for example La_{0.5}Sr_{1.5}MnO₄₋ₓ. Furthermore, a combination with small amounts of metals from the group gold, silver and palladium is possible.

In this case, the sintering shrinkage and the thermal expansion coefficient of the heater material may be configured in such a way that they are as close as possible to the behavior of the ceramic substrate material LTCC. To this end, for example, a filler having a thermal expansion coefficient in a range of <4.0*10⁻⁶K⁻¹ may be embedded in the heater material, for example cordierite. In this way, particularly good thermal stability and reliability are provided, which increases the long-term stability considerably.

In the scope of another preferred configuration of the electronic component according to the invention, the electronic component is part of a sensor, in particular of an exhaust gas sensor. The component according to the invention is particularly highly suitable for such applications in particular, since it combines good thermal stability with good insulation properties of the ceramic substrate with good signal transmission.

The present invention furthermore relates to a method for producing an electronic component according to the invention, comprising the steps:
providing a ceramic substrate, the ceramic substrate having an alkali metal compound content of ≦0.5%, in particular ≦0.05%, and the ceramic substrate being selected from the group consisting of a ceramic substrate comprising aluminum oxide, anorthite, a filler having a thermal expansion coefficient of ≦4.0*10⁻⁶K⁻¹ and glass, a ceramic substrate comprising aluminum oxide, celsian, a filler having a thermal expansion coefficient of ≦4.0*10⁻⁶K⁻¹ and glass, and a ceramic substrate comprising an alkaline-earth metal silicate glass having a silicon dioxide content in a range of >50 mol %, boron oxide, and a filler having a thermal expansion coefficient of 4.0*10⁻⁶K⁻¹,
shaping a green body by extrusion or injection molding of the ceramic substrate,
applying at least one functional layer, for instance a metal conductor track, onto the green body, and
sintering the green body.

The method according to the invention may contain further steps, which are sufficiently known to the person skilled in the art for the production of an electronic component. For example, the green body may be further adapted in terms of its shape before the sintering, for instance by a grinding process or division. Furthermore, the green body may be debinded.

As the functional layer, besides a conductor track, an insulation layer may for example also be applied, which may comprise the same ceramic material as the ceramic substrate. Furthermore, the application of a heating element, for instance a heating resistor layer, is possible. The functional layers may, for instance, be applied onto the green body by printing. It is furthermore possible, as is known in LTCC technology, for a multiplicity of such layers to be stacked on one another before the sintering, so as also to allow internal structures on functional elements.

The present invention furthermore relates to the use of a ceramic carrier which comprises a ceramic substrate that has an alkali metal compound content of ≦0.5%, in particular ≦0.05%, wherein the ceramic substrate is selected from the group consisting of a ceramic substrate comprising aluminum oxide, anorthite, a filler having a thermal expansion coefficient of ≦4.0*10⁻⁶K⁻¹ and glass, a ceramic substrate comprising aluminum oxide, celsian, a filler having a thermal expansion coefficient of ≦4.0*10⁻⁶K⁻¹ and glass, and a ceramic substrate comprising an alkaline-earth metal silicate glass having a silicon dioxide content in a range of >50 mol %, boron oxide, and a filler having a thermal expansion coefficient of ≦4.0*10⁻⁶K⁻¹, as a carrier substrate for a semiconductor element for high temperature applications in a temperature range of ≧250° C., in particular ≧400° C.

For example, the invention comprises a use for applications of ChemFET semiconductor chips, sensors based on membranes, for instance pressure sensors, consisting of silicon carbide or silicon on sintered LTCC, or of gastight and high temperature stable packaging methods for semiconductor components.

Primarily, application for a field-effect transistor chip based on silicon carbide in an exhaust gas sensor application is provided. In principle, however, other applications may be envisioned with silicon or silicon carbide chips, which are used for example as pressure sensors at elevated temperatures. Furthermore, applications of semiconductor components which need to be isolated in a hermetically sealed manner against the surrounding atmosphere as well as against high pressures, and which are intended to permit signal take-off on the pressureless or pollutant gas-free side, may also be envisioned.

Further advantages and advantageous configurations of the subject-matter according to the invention are illustrated by the drawings and explained in the following description. In this context, it should be noted that the drawings are only descriptive in nature and are not intended to restrict the invention in any way.

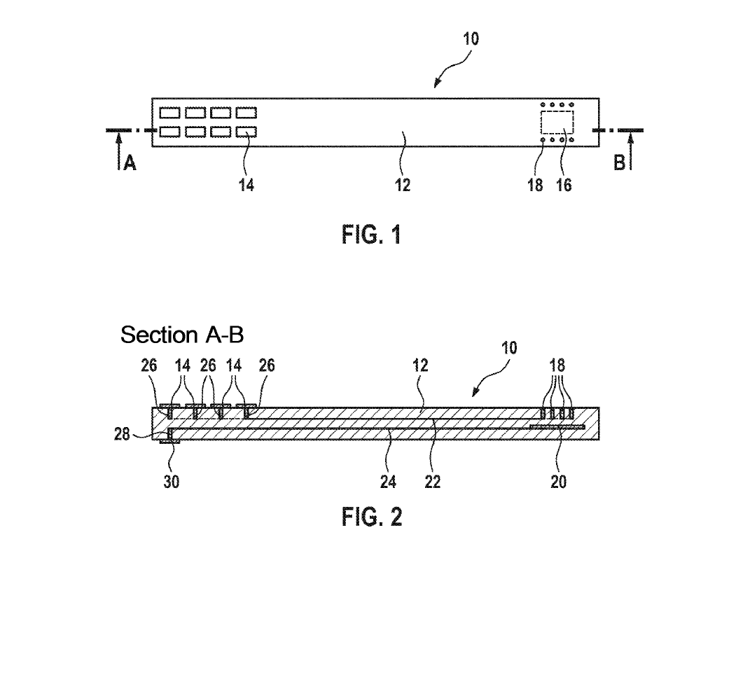

FIG. 1 shows a schematic plan view of an embodiment of a component according to the invention;

FIG. 2 shows a schematic side view through the embodiment according to FIG. 1 along the plane A-B.

FIG. 1 shows an electronic component 10 according to the invention. The electronic component 10 is, in particular, suitable for high temperature applications in a temperature range of ≧250° C., in particular ≧400° C. The component 10 comprises a ceramic carrier 12, on which for example plug-in contacts 14 for electrical contacting may be arranged. The ceramic carrier 12 comprises a ceramic substrate, which has an alkali metal compound content of ≦0.5%, in particular ≦0.05%, the ceramic substrate being selected from the group consisting of a ceramic substrate comprising aluminum oxide, anorthite, a filler having a thermal expansion coefficient of ≦4.0*10⁻⁶K⁻¹ and glass, a ceramic substrate comprising aluminum oxide, celsian, a filler having a thermal expansion coefficient of ≦4.0*10⁻⁶K⁻¹ and glass, and a ceramic substrate comprising an alkaline-earth metal silicate glass having a silicon dioxide content in a range of >50 mol %, boron oxide, and a filler having a thermal expansion coefficient of ≦4.0*10⁻⁶K⁻¹.

The filler may be selected from the group consisting of cordierite, mullite, silicon nitride, silicon carbide, glass having a silicon dioxide content in a range of >50 mol %, or quartz glass, and it may furthermore comprise sintering aids, for instance titanium dioxide or zirconium dioxide.

For example, a semiconductor element 16, for example having through-holes 18 for electrical contacting of the semiconductor element 16, is arranged on the opposite side of the carrier 12 from the plug-in contacts 14. Depending on the embodiment, a multiplicity of semiconductor elements 16 may also be arranged on the carrier 12.

The electrical contacting may for example, be carried out by wire bonding methods, if for example an arrangement is selected in which through-holes 18 arranged beside the mounting position of the electronic semiconductor element 16 are filled with an electrically conductive material. These may also be arranged below the semiconductor element 16 and the electrical contacting may, for example, be carried out with a noble metal paste, which is sinterable at low temperatures, directly to the contact faces of the electronic component 16 which are turned in the direction of the carrier 12.

Depending on the semiconductor element or elements 16, the component 10 may for example be part of a sensor, in particular of an exhaust gas sensor. Particularly in the case of a sensor, it may be preferred for an electrically heatable heating element 20 to be arranged inside the ceramic carrier 12, as can be seen in FIG. 2. The heating element 20 may, for example, be formed as a heating resistor layer and may comprise a metallic material, which comprises a noble metal or a noble metal alloy and at least one resistance-increasing material. In an alternative, the heating element 20 may comprise a composite consisting of glass and at least one electrically conductive metal oxide, in particular ruthenium dioxide.

FIG. 2 furthermore shows by way of example two conductor tracks 22, 24, which may be configured according to the function of the component 10. For example, the conductor track 22 may connect the through-holes 18 to the plug-in contacts 14, or to through-holes 26 connected to the plug-in contacts 14, while the conductor track 24 connects the heating element 20 to an outer terminal 30 via a through-hole 28.

1. An electronic component for high temperature applications at a temperature of greater than or equal to 250° C. comprising:
a ceramic carrier including a ceramic substrate having an alkali metal compound content of less than or equal to 0.5%; and
a semiconductor element,
wherein the ceramic substrate is selected from the group consisting of (i) a first ceramic substrate comprising aluminum oxide, anorthite, a filler having a thermal expansion coefficient of less than or equal to 4.0*10⁻⁶K⁻¹ and glass, (ii) a second ceramic substrate comprising aluminum oxide, celsian, a filler having a thermal expansion coefficient of less than or equal to 4.0*10⁻⁶K⁻¹ and glass, and (iii) a third ceramic substrate comprising an alkaline-earth metal silicate glass having a silicon dioxide content greater than 50 mol %, boron oxide, and a filler having a thermal expansion coefficient of less than or equal to 4.0*10⁻⁶K⁻¹.

2. The electronic component as claimed in claim 1, wherein the ceramic substrate has a thermal expansion coefficient in a range of from 3.0*10⁻⁶K⁻¹ to 4.5*10⁻⁶K⁻¹.

3. The electronic component as claimed in claim 1, wherein the filler contained in the ceramic substrate is selected from the group consisting of cordierite, mullite, silicon nitride, silicon carbide, glass having a silicon dioxide content of greater than 50 mol %, and quartz glass.

4. The electronic component as claimed in claim 1, wherein the ceramic substrate includes at least one sintering aid.

5. The electronic component as claimed in claim 1, wherein an electrically heatable heating element is positioned inside the ceramic carrier.

6. The electronic component as claimed in claim 5, wherein the heating element includes a metallic material, which has (i) one of a noble metal and a noble metal alloy and (ii) at least one resistance-increasing material.

7. The electronic component as claimed in claim 5, wherein the heating element includes a composite of glass and an electrically conductive metal oxide.

8. The electronic component as claimed in claim 1, wherein the electronic component is installed in a sensor.

9. A method for producing an electronic component comprising:
providing a ceramic substrate having an alkali metal compound content of less than or equal to 0.5%, the ceramic substrate being selected from the group consisting of (i) a first ceramic substrate comprising aluminum oxide, anorthite, a filler having a thermal expansion coefficient of less than or equal to 4.0*10⁻⁶K⁻¹ and glass, (ii) a second ceramic substrate comprising aluminum oxide, celsian, a filler having a thermal expansion coefficient of less than or equal to 4.0*10⁻⁶K⁻¹ and glass, and (iii) a third ceramic substrate comprising an alkaline-earth metal silicate glass having a silicon dioxide content of greater than 50 mol %, boron oxide, and a filler having a thermal expansion coefficient of less than or equal to 4.0*10⁻⁶K⁻¹,
shaping a green body by extrusion or injection molding of the ceramic substrate,
applying at least one functional layer onto the green body, and
sintering the green body.

10. A carrier substrate for a semiconductor element for high temperature applications at a temperature greater than or equal to 250° C. comprising:
a ceramic carrier including a ceramic substrate that has an alkali metal compound content of less than or equal to 0.5%,
wherein the ceramic substrate is selected from the group consisting of (i) a first ceramic substrate comprising aluminum oxide, anorthite, a filler having a thermal expansion coefficient of less than or equal to 4.0*10⁻⁶K⁻¹ and glass, (ii) a second ceramic substrate comprising aluminum oxide, celsian, a filler having a thermal expansion coefficient of less than or equal to 4.0*10⁻⁶K⁻¹ and glass, and (iii) a third ceramic substrate comprising an alkaline-earth metal silicate glass having a silicon dioxide content of greater than 50 mol %, boron oxide, and a filler having a thermal expansion coefficient of less than or equal to 4.0*10⁻⁶K⁻¹.

11. The electronic component as claimed in claim 1, wherein the electronic component is configured for high temperature applications at a temperature of greater than or equal to 400° C.

12. The electronic component as claimed in claim 1, wherein the alkali metal compound content of the ceramic substrate is less than or equal to 0.05%

13. The electronic component as claimed in claim 2, wherein the thermal expansion coefficient of the ceramic substrate is in a range of from 4.0*10⁻⁶K⁻¹ to 4.2*10⁻⁶K⁻¹

14. The electronic component as claimed in claim 4, wherein the at least one sintering aid includes one of titanium dioxide and zirconium dioxide.

15. The electronic component as claimed in claim 7, wherein the electrically conductive metal oxide includes ruthenium dioxide.

16. The electronic component as claimed in claim 8, wherein the electronic component is installed in an exhaust gas sensor.

17. The method as claimed in claim 9, wherein the alkali metal compound content of the ceramic substrate is less than or equal to 0.05%.

18. The method as claimed in claim 9, wherein the application of the at least one functional layer includes applying at least one metal conductor track onto the green body.

19. The carrier substrate as claimed in claim 10, wherein the semiconductor element is configured for high temperature applications at a temperature of greater than or equal to 400° C.

20. The carrier substrate as claimed in claim 10, wherein the alkali metal compound content of the ceramic substrate is less than or equal to 0.05%
